(19) United States
(12) Patent Application Publication
(10) Pub. No.: US 2025/0067915 A1
(43) Pub. Date: Feb. 27, 2025

(54) THIN FILM TYPE FILTER FOR ATTENUATING LIGHT AND METHOD OF PRODUCING THE SAME

(71) Applicant: NALUX CO., LTD., Osaka (JP)

(72) Inventor: Masanori ENDO, Osaka (JP)

(73) Assignee: NALUX CO., LTD., Osaka (JP)

(21) Appl. No.: 18/940,077

(22) Filed: Nov. 7, 2024

Related U.S. Application Data
(63) Continuation of application No. PCT/JP2022/024675, filed on Jun. 21, 2022.

(51) Int. Cl. G02B 5/22; C23C 14/08; G02B 1/10

(52) U.S. Cl. CPC G02B 5/223; C23C 14/085; G02B 1/10

(57) ABSTRACT

A thin film type filter for attenuating light comprising a multilayer film including a layer or layers of iron oxide and a layer or layers of other material having refractive index lower than refractive index of iron oxide, wherein the multilayer is made up of alternate layers of iron oxide and of other material, a ratio of the number of iron atoms to the number of oxygen atoms in each layer of iron oxide is equal to or greater than 4/3 and less than 3/2 and an attenuation coefficient of each layer of iron oxide is equal to or greater than 0.1 for light of wavelength of a certain wavelength in a wavelength from 700 nanometers to 2000 nanometers.

### CROSS REFERENCE TO RELATED APPLICATION

This is a Continuation of International Patent Application No. PCT/JP2022/024675 filed Jun. 21, 2022, which designates the U.S. The content of this application is hereby incorporated by reference.

### TECHNICAL FIELD

The present invention relates to a thin-film type filter for attenuating light used for a wavelength range of 700-2000 nanometers and a method of producing the same.

### BACKGROUND ART

As a filter for attenuating light used for a wavelength range of 700-2000 nanometers, filters that use a plastic to which an attenuating agent such as carbon black or titanium pigment is added are widely known. For production of a plastic to which an attenuating agent is added, however, equipment for mixing the plastic and the attenuating agent is required and in the process of production, it is not easy to adjust an attenuation coefficient of the plastic to which the attenuating agent is added. Further, anti-reflection coating is required to prevent stray light caused by reflection on a surface of the plastic. Thus, in order to produce a filter that uses a plastic to which an attenuating agent is added, dedicated equipment and a lot of time for adjustment are required, which leads to a higher production cost.

On the other hand, thin film type filters for attenuating near infrared rays have been developed (for example, Patent document 1). Conventional thin-film type filters for attenuating near infrared rays, including the one described in Patent document 1 are not satisfactory from the viewpoint of optical performance and environmental resistance. Further, a method of producing a thin-film type filter for attenuating near infrared rays, which is satisfactory from the viewpoint of optical performance and environmental resistance, with high stability has not been developed.

Accordingly, there is a need for a thin-film type filter for attenuating near infrared rays, which is satisfactory from the viewpoint of optical performance and environmental resistance, and a method of producing a thin-film type filter for attenuating near infrared rays, which is satisfactory from the viewpoint of optical performance and environmental resistance, with high stability.

### PRIOR ART DOCUMENT

### Patent document

Patent Document 1: JP2000352612A

The object of the present invention is to provide a thin-film type filter for attenuating near infrared rays, which is satisfactory from the viewpoint of optical performance and environmental resistance, and a method of producing a thin film type filter for attenuating near infrared rays, which is satisfactory from the viewpoint of optical performance and environmental resistance, with high stability.

### SUMMARY OF THE INVENTION

A thin film type filter for attenuating light according to a first aspect of the present invention includes a multilayer film including a layer or layers of iron oxide and a layer or layers of other material having refractive index lower than refractive index of iron oxide. The multilayer is made up of alternate layers of iron oxide and of other material, a ratio of the number of iron atoms to the number of oxygen atoms in each layer of iron oxide is equal to or greater than 4/3 and less than 3/2 and an attenuation coefficient of each layer of iron oxide is equal to or greater than 0.1 for light of wavelength of a certain wavelength in a wavelength from 700 nanometers to 2000 nanometers.

The thin-film type filter for attenuating light according to the present aspect is provided with the multilayer in which a ratio of the number of iron atoms to the number of oxygen atoms in each layer of iron oxide is equal to or greater than 4/3 and less than 3/2 and an attenuation coefficient of each layer of iron oxide is equal to or greater than 0.1 for light of a certain wavelength in a wavelength from 700 nanometers to 2000 nanometers. Thanks to the multilayer described above, transmittance can be determined with a high degree of accuracy and a high environmental resistance can be realized.

In the thin-film type filter for attenuating light according to a first embodiment of the present aspect, the multilayer film includes plural layers of iron oxide and the maximum difference in attenuation coefficient between two layers of the plural layers of iron oxide is equal to or greater than 0.1 for light of a certain wavelength in a wavelength from 700 nanometers to 2000 nanometers.

In the thin film type filter for attenuating light according to the present embodiment, the multilayer film includes plural layers of iron oxide and the maximum difference in attenuation coefficients of the plural layers of iron oxide is equal to or greater than 0.1 for light of a certain wavelength in a wavelength from 700 nanometers to 2000 nanometers. Thanks to the multilayer described above, transmittance of any value from 10% to 90% can be realized.

In the thin-film type filter for attenuating light according to a second embodiment of the present aspect, the value of thickness of the layer of iron oxide or the sum of the values of thickness of the layers of iron oxide is less than 500 nanometers.

In the thin-film type filter for attenuating light according to a third embodiment of the present aspect, the multilayer film is provided on a plastic substrate.

A method of producing a thin film type filter for attenuating light according to a second aspect of the present invention is a method of producing a thin film type filter including a multilayer film including a layer or layers of iron oxide and a layer or layers of other material having refractive index lower than lower than refractive index of iron oxide. The method includes making up alternate layers of iron oxide and of other material, a ratio of the number of iron atoms to the number of oxygen atoms in each layer of iron oxide being equal to or greater than 4/3 and less than 3/2 and an attenuation coefficient of each layer of iron oxide being equal to or greater than 0.1 for light of wavelength of a certain wavelength in a wavelength from 700 nanometers to 2000 nanometers. In the method, absorption of light of the multilayer film is adjusted by changing the ratio of the number of iron atoms to the number of oxygen atoms in each layer of iron oxide and the value of thickness of the layer of iron oxide or the sum of the values of thickness of the layers of iron oxide.

The method according to the present aspect includes making up alternate layers of iron oxide and of other material, a ratio of the number of iron atoms to the number of oxygen atoms in each layer of iron oxide being equal to or greater than 4/3 and less than 3/2 and an attenuation coefficient of each layer of iron oxide being equal to or greater than 0.1 for light of a certain wavelength in a wavelength from 700 nanometers to 2000 nanometers. Thanks to the features described above, a thin film type filter for attenuating light that has transmittance determined with a high degree of accuracy and a high environmental resistance for light of wavelength of a certain wavelength in a wavelength from 700 nanometers to 2000 nanometers can be produced by the method. Further, since in the method according to the present aspect, absorption of light of the multilayer film is adjusted by changing the ratio of the number of iron atoms to the number of oxygen atoms in each layer of iron oxide and the value of thickness of the layer of iron oxide or the sum of the values of thickness of the layers of iron oxide, a thin-film type filter for attenuating light that has transmittance of any value from 10% to 90% determined with a high degree of accuracy can be easily produced by the method.

In the method of producing a thin film type filter for attenuating light according to a first embodiment of the second aspect of the present invention, the multilayer film is formed in such a way that the multilayer film includes plural layers of iron oxide and the maximum difference in attenuation coefficient between two layers of the plural layers of iron oxide is equal to or greater than 0.1 for light of wavelength of a certain wavelength in a wavelength from 700 nanometers to 2000 nanometers.

Since in the method of producing a thin film type filter for attenuating light according to the present embodiment, the multilayer film is formed in such a way that the maximum difference in attenuation coefficient between two layers of the plural layers of iron oxide is equal to or greater than 0.1 for light of a certain wavelength in a wavelength from 700 nanometers to 2000 nanometers, a thin-film type filter for attenuating light having transmittance of any value from 10% to 90% can be easily produced.

In the method of producing a thin film type filter for attenuating light according to a second embodiment of the second aspect of the present invention, the multilayer film is formed using a vacuum deposition method or a spattering method.

### BRIEF DESCRIPTION OF DRAWINGS

FIG. 1 shows constituent pieces of a thin film type filter for attenuating light;

FIG. 2 is a flowchart for describing how to produce a thin film type filter for attenuating light according to an embodiment of the present invention;

FIG. 3 is a flowchart for describing step S1010 of FIG. 2;

FIG. 4 shows refractive index (n) of each of layers A-Din a wavelength range of visible and near infrared rays;

FIG. 5 shows attenuation coefficient (k) of each of layers A-D in a wavelength range of visible and near infrared rays;

FIG. 6 shows transmittance of layer A in a wavelength range of near infrared rays before and after an environmental test;

FIG. 7 shows transmittance of layer B in a wavelength range of near infrared rays before and after an environmental test;

FIG. 8 shows transmittance of layer C in a wavelength range of near infrared rays before and after an environmental test;

FIG. 9 shows transmittance and reflectance in a wavelength range of near infrared rays of the thin-film type filter for attenuating light of Example 1;

FIG. 10 shows transmittance and reflectance in a wavelength range of near infrared rays of the thin-film type filter for attenuating light of Example 2; and

FIG. 11 shows transmittance before and after an environmental test in a wavelength range of near infrared rays of the thin-film type filter for attenuating light of Example 1.

### DESCRIPTION OF EMBODIMENTS

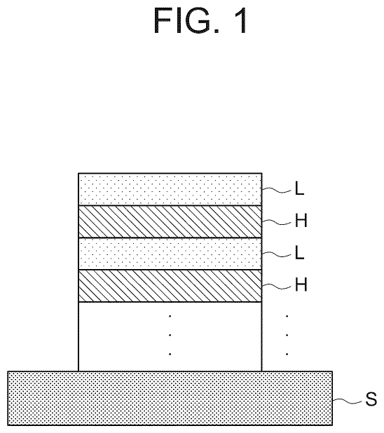

FIG. 1 shows constituent pieces of a thin film type filter for attenuating light. The thin-film type filter for attenuating light is a multilayer film formed on a substrate S. The multilayer film is formed on the substrate S as alternate layers of a layer represented by L in the drawing and made of a material having a relatively low refractive index and a layer represented by H in the drawing and made of a material having a relatively high refractive index. A layer made of a material having a relatively low refractive index and the layer made of a material having a relatively high refractive index are also referred to respectively as a L layer and an H layer. Plural L layers can be made of different materials and plural H layers can be made of different materials.

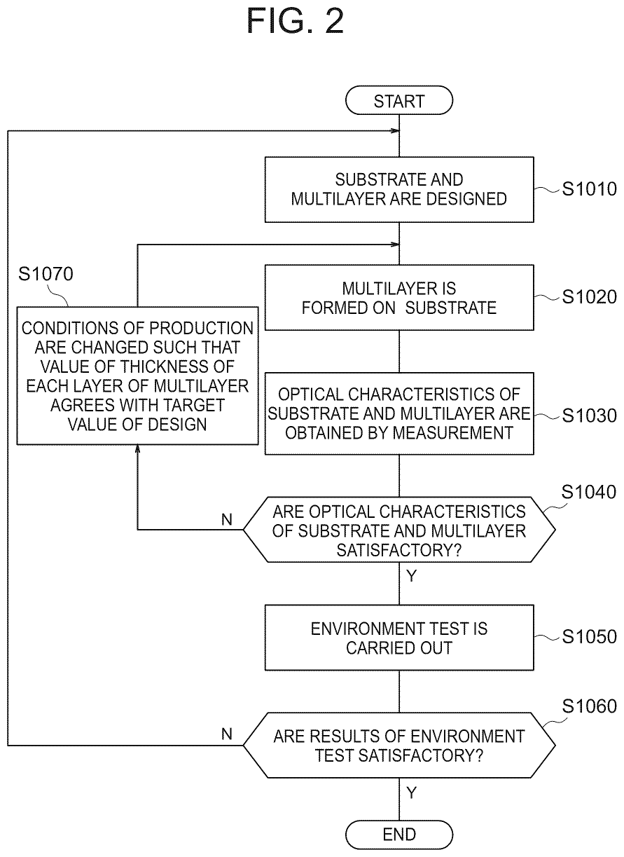

FIG. 2 is a flowchart for describing how to produce a thin-film type filter for attenuating light according to an embodiment of the present invention.

In step S1010 of FIG. 2, a substrate and a multilayer are designed such that a target value of transmittance and a target value of reflectance of the thin-film type filter for attenuating light can be realized.

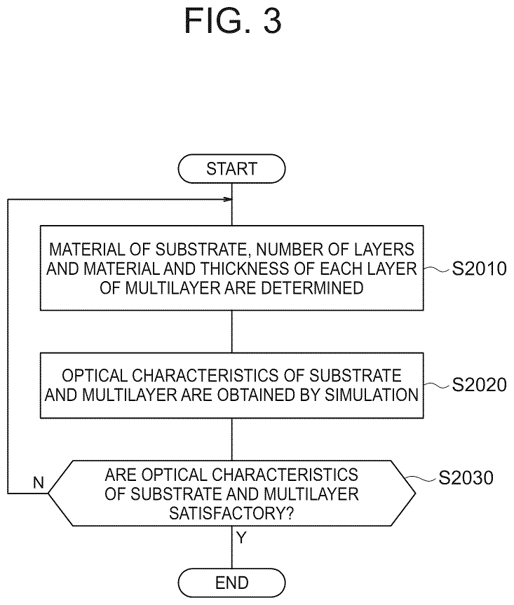

FIG. 3 is a flowchart for describing step S1010 of FIG. 2.

In step S2010 of FIG. 3, material of the substrate S, each L layer and each H layer, an arrangement and the number of the L and H layers and thickness of each L layer and each H layer are provisionally determined.

In step S2020 of FIG. 3, optical characteristics such as transmittance and reflectance of the substrate and the multilayer are obtained by simulation using an optical thin film design software.

In step S2030 of FIG. 3, it is determined whether the optical characteristics such as transmittance and reflectance of the substrate and the multilayer are satisfactory or not. If satisfactory, the process is terminated. If not satisfactory, the process returns to step S2010 and at least one of material of the substrate S, each L layer and each H layer, an arrangement and the number of the L and H layers and thickness of each L layer and each H layer is changed.

In step S1020 of FIG. 2, a multilayer is formed on the substrate S. The multilayer is formed using a vacuum deposition method, a spattering method or the like.

In step S1030 of FIG. 2, optical characteristics such as transmittance and reflectance of the substrate and the multilayer are obtained by measurement.

In step S1040 of FIG. 2, it is determined whether the optical characteristics such as transmittance and reflectance of the substrate and the multilayer are satisfactory or not. If satisfactory, the process goes to step S1050. If not satisfactory, the process goes to step S1070.

In step S1050 of FIG. 2, an environment test is carried out.

In step S1060 of FIG. 2, it is determined whether results of the environment test are satisfactory or not. If satisfactory, the process is terminated. If not satisfactory, the process returns to step S1010 and the substrate and the multilayer are redesigned while shifting the priority from the optical characteristics such as transmittance and reflectance to environmental resistance.

In step S1070 of FIG. 2, conditions of the production are changed in order that the value of thickness of each layer of the multilayer agrees with the target value of the design and then the process returns to step S1020.

H layers of the multilayer film will be described below. Attenuation coefficients of H layers are important in order to realize a desired value of transmittance of a filter for attenuating light. From the viewpoint of attenuation coefficients, it is common to use metal or metal oxide as material of H layers.

Table 1 shows properties including attenuation coefficients of a typical metal film and a metal-oxide film that are used as material of H layers.

TABLE 1

| | | | | Film thickness of |
|---|---|---|---|---|
| | | Optical constants | | absorptance of 50% |
| Material | x | n | k | (nm) |
| Ni | — | 2.5 | 5.6 | 10 |
| TiOx | 1.5~1.67 | 2.46 | 0.55 | 100 |

In Table 1, n represents reflectance index and k represents an attenuation coefficient. The numerical values shown in Table 1 are those for light at the wavelength of 1000 nanometers.

In order to obtain a desired value of transmittance of the filter for attenuating light, in step S1020 of FIG. 2, thickness of each layer of the multilayer film must be controlled such that the value of thickness agrees with a designed target value with a high degree of accuracy. According to Table 1, absorptance of the nickel layer is 50% when the thickness is 10 nanometers and absorptance of the titanium oxide layer is 50% when the thickness is 100 nanometers. Accordingly, when transmittance is controlled by changing thickness of a layer and thus changing absorptance of the layer, an influence of a certain amount of change in thickness to absorptance is smaller in the case of the titanium oxide layer than in the case of the nickel layer and therefore a higher degree of accuracy in transmittance is expected in the case of the titanium oxide layer. In general, an attenuation coefficient of a metal layer is too great to obtain a high degree of accuracy in transmittance and therefore a metal-oxide layer is preferable to a metal layer in order to obtain a high degree of accuracy in transmittance.

Conventionally, a titanium oxide layer is often used as material of an H layer of a thin-film type filter for attenuating light such as an ND filter. Although a titanium oxide layer has an attenuation coefficient that is appropriate for far-red light from the viewpoint of easiness of obtaining a high degree of accuracy in transmittance as described above, optical properties of the titanium oxide layer greatly vary with time.

The inventor has selected iron oxide as material of H layers of a thin film type filter for attenuating light. The reasons are that a layer of iron oxide can be formed using a vacuum deposition method, that particularly tri-iron tetroxide (Fe₃O₄) is one of few materials that have a high value of absorptance for visible and far-red light and that it is expected that variation in optical properties with time can be reduced. When iron oxide layers are formed, a vacuum deposition method is carried out using powder of tri-iron tetroxide on the market as deposition material.

Tables 2 shows an example of conditions under which the vacuum deposition method is carried out.

TABLE 2

| Item | |
|---|---|
| Material of deposition | Powder of triiron tetraoxide |
| Vaporizing method of | Heating using electron beam |
| material | (EB) |
| Pressure in chamber | 10⁻³-10⁻² Pa |
| Type of atmosphere | Oxygen |
| gas | |
| Flow rate of | 200 sccm or smaller |
| atmosphere gas | |

In Table 2 “sccm” means standard cubic centimeters per minute. The inventor has made a finding that iron and oxygen components of iron oxide varies by a small change in flow rate of oxygen gas in the process of vacuum deposition and this causes a great change in optical features of a layer of iron oxide.

Table 3 shows optical features of layers of iron oxide.

TABLE 3

| | | | | Film thickness of |
|---|---|---|---|---|
| | | Optical constants | | absorptance of 50% |
| | x of FeOx | n | k | (nm) |
| Layer A | 1.29 | 2.28 | 0.35 | 158 |
| Layer B | 1.35 | 2.33 | 0.36 | 153 |
| Layer C | 1.47 | 2.38 | 0.17 | 324 |
| Layer D | 1.5 | 2.47 | 0.003 | 17819 |

Each of layers A-D in Table 3 is a single-layer film made of FeOx formed on a glass substrate. Layer A is a layer of iron oxide formed without bringing oxygen into the atmosphere gas. Layer B is a layer of iron oxide formed in a process, operating conditions of which are given in Table 2 including a flow rate of oxygen gas. Layer C is a layer of iron oxide formed in a process, in which a flow rate of oxygen gas is greater than in the case of layer B. Layer D is a layer of iron oxide formed in a process, in which a flow rate of oxygen gas is sufficiently great. Values of x of layers A-D are 1.29 [symbol] 1.35 [symbol] 1.47 and 1.5, respectively. The values of x are obtained in the following procedure using a quartz oscillator of a film thickness monitor that measures film thickness by monitoring a change in resonance frequency of the quartz oscillator, the change being caused by a change in weight of the quartz oscillator due to material deposed thereon. At first, each of FeOx films, more specifically layers A-D, formed on the quartz oscillator is heated and completely oxidized to obtain an Fe₂O₃ film. Then, the number of added oxygen atoms is obtained from a difference between the weight of the quartz oscillator before the complete oxidation and the weight of the quartz oscillator thereafter. Then, from the weight of the Fe₂O₃ film after the complete oxidation, the number of iron atoms are obtained. Finally, x is estimated from the number of iron atoms after the complete oxidation and the number of added oxygen atoms.

In Table 3 n represents refractive index and k represents an attenuation coefficient. The values in the table are those for light of wavelength of 1000 nanometers. How to determine n and k will be described below. Reflectance and transmittance for light of wavelength of 1000 nanometers of each of layers A-D formed on a glass substrate are measured. Transmittance is obtained using a ratio of intensity of transmitted light to intensity of incident light of a glass substrate with a single film formed thereon and a ratio of intensity of transmitted light to intensity of incident light of the glass substrate alone. Using a film designing software on the market (for example, Essential Macleod, Optical layer or the like), values of n, k and film thickness (thickness of a layer) can be uniquely determined from three or more sets of measured data of transmittance, reflectance, an angle of incidence and s-/p-polarized light.

Absorptance is a ratio of intensity I of delivered light to intensity I₀ of incident light and defined by the following expression.

$$\frac{I}{{I}_{0}} = exp ( - \frac{4 π \cdot k \cdot d}{λ} )$$

d represents optical path length of film thickness and λ represents wavelength of light.

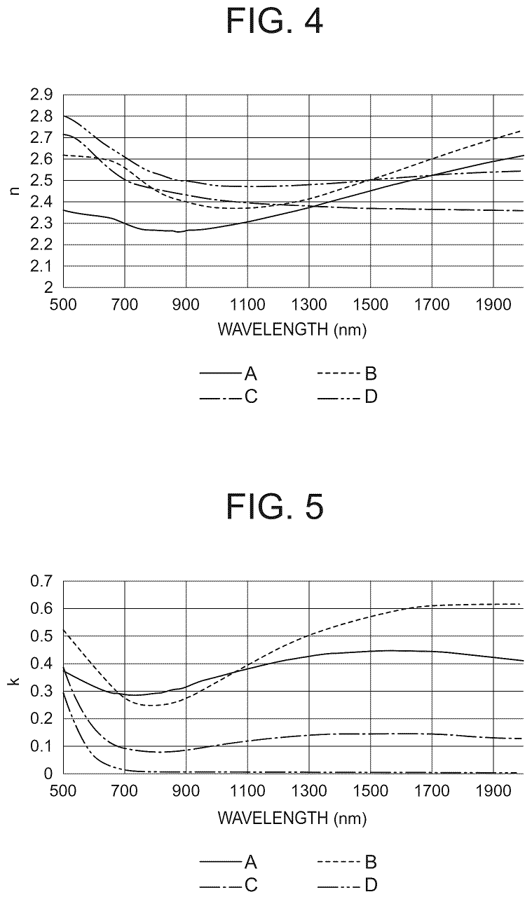

FIG. 4 shows refractive index (n) of each of layers A-D in a wavelength range of visible and near infrared rays. The horizontal axis of FIG. 4 indicates wavelength and the vertical axis of FIG. 4 indicates refractive index. The unit of wavelength is nanometer.

FIG. 5 shows attenuation coefficient (k) of each of layers A-D in a wavelength range of visible and near infrared rays. The horizontal axis of FIG. 5 indicates wavelength and the vertical axis of FIG. 5 indicates attenuation coefficient. The unit of wavelength is nanometer.

According to Table 3 and FIG. 5, the value of attenuation coefficient of layer D is far smaller than the values of attenuation coefficient of layers A-C. The reason will be described below. The reason that the values of attenuation coefficient of layers A-C are relatively great is that each of layers A-C contains both ferrous iron and ferric iron. In layers A-C, electron transition occurs between ferrous iron and ferric iron. This electron transition is an allowed transition and an amount of absorbed light is relatively great and therefore each of layers A-C has a relatively great attenuation coefficient. On the other hand, layer D does not contain ferrous iron and therefore in layer D, d-d transition in ferric iron of ferric oxide (Fe₂O₃) alone occurs. This electron transition is an forbidden transition and an amount of absorbed light is relatively small and therefore layer D has a remarkably small attenuation coefficient. Thus, it should be noted that the value of attenuation coefficient changes by a large amount depending on the value of x of FeOx.

It should also be noted that the value of attenuation coefficient of layer D in the wavelength range over 700 nanometers is far smaller than that in the visible light wavelength range.

Further, it should be noted that the value of attenuation coefficient of layer C is far greater than that of layer D, because layer C contains a very small amount of ferric iron although a difference between the value of x of layer C and the value of x of layer D is very small.

According to Table 3, a value of thickness of layer D required to obtain absorptance of 50 percent is 5 to 11 times as great as that of each of layers A-C. Accordingly, deposition time of D layer is greater than that of each of layers A-C and therefore efficiency in production of D layer is relatively low. Further, in general, a change in stress in a film due to a change in environmental conditions increases with film thickness and a crack is liable to be generated in a relatively thick film and thus, environmental resistance deteriorates. Accordingly, from the viewpoint of absorbance, layer D is not desirable for an Hlayer. When the values of attenuation coefficient shown in Table 3 and FIG. 5 are observed, layers A-C are desirable for H layesr from the viewpoint of absorbance. Further, the value of attenuation coefficient of each of layer A and layer B is far greater than the value of attenuation coefficient of layer C and therefore from the viewpoint of absorbance, layer A and layer B are preferable to layer C for a wide range of applications.

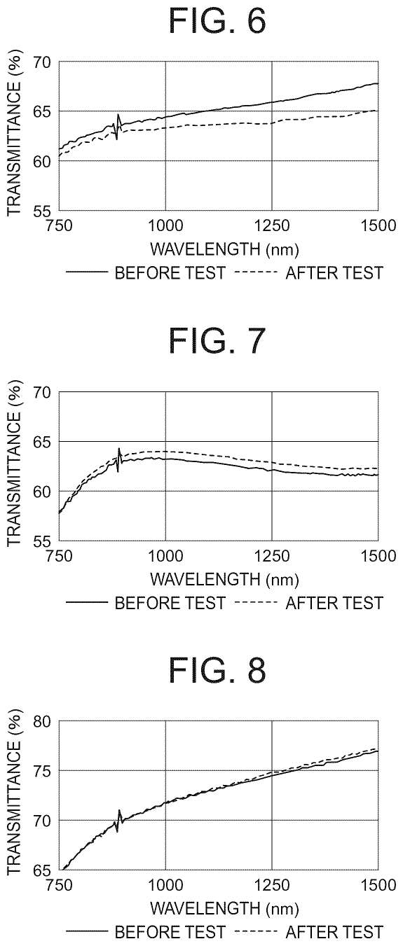

FIG. 6 shows transmittance of layer A in a wavelength range of near infrared rays before and after an environmental test.

FIG. 7 shows transmittance of layer B in a wavelength range of near infrared rays before and after an environmental test.

FIG. 8 shows transmittance of layer C in a wavelength range of near infrared rays before and after an environmental test.

The horizontal axis of each of FIGS. 6-8 indicates wavelength and the vertical axis of each of FIGS. 6-8 indicates transmittance. The unit of wavelength is nanometer and the unit of transmittance is percent. In the environmental test, each of layers A-C formed on a substrate was held for 72 hours in conditions of temperature of 60 degrees centigrade and a relative humidity of 90 percent.

When FIGS. 6-8 are observed, a change in transmittance before and after the environmental test of layer A is greater than that of layer B and that of layer C. Accordingly, from the viewpoint of environmental resistance, each of layer B and layer C is preferable to layer A.

As described above, iron oxide FeOx can contain both ferrous iron and ferric iron. FeO consists of ferrous iron alone and Fe₂O³ consists of ferric iron alone. In general, the greater x of FeOx is and the smaller an amount of ferrous iron is (the closer to Fe₂O₃ the iron oxide is), environmental resistance increases. The reasons are that an apparent change in optical properties becomes smaller and oxidation rate is reduced because an amount of ferrous iron becomes smaller.

Accordingly, a range of x of iron oxide (FeOx) that is desirable for the H layer from the viewpoint of attenuation coefficient (absorptance) and environmental resistance is as below.

$$\frac{4}{3} \leq x < \frac{3}{2} \qquad ( 1 )$$

When x of an iron oxide (FeOx) layer satisfies Expression (1) like layer B and layer C, the attenuation coefficient of the iron oxide layer is 0.1 or greater for light of a certain wavelength in a wavelength range of 700-2000 nanometers.

Concerning Expression (1), x can be greater than 4/3 in consideration of environmental resistance.

When a multilayer film is designed in step S1010 of FIG. 2, the degree of freedom of design is improved by the use of a combination of an H layer that has a relatively high attenuation coefficient like layer B and an H layer that has a relatively low attenuation coefficient like layer C so that a wide range of transmittance of a thin-film type filter for attenuating light can be realized more easily.

Examples of the present invention will be described below.

Table 4 shows constituent pieces of thin-film type filters for attenuating light of Example 1 and Example 2 of the present invention. Each of the thin-film type filters for attenuating light of Example 1 and Example 2 is a multilayer film formed on a plastic substrate. The multilayer film is formed as alternate layers of a L layer and an H layer. Material of the plastic substrate is polyetherimide and the refractive index for light of wavelength of 850 nanometers is 1.64. The multilayer film of Example 1 has 7 layers. The layer adjacent to the substrate is referred to as a first layer and the outermost layer is referred to as a seventh layer. Each of the seven layers is respectively a L layer, an H layer, a L layer, an H layer, a L layer, an H layer and a L layer from the first layer to the seventh layer. Material of the first layer as a L layer is aluminum oxide (Al₂O₃) and material of the other L layers is silicon dioxide (SiO₂). Each of the H layers is layer B previously described. The sum of values of thickness of the H layers of the multilayer film of Example 1 is 147 nanometers. The multilayer film of Example 2 has 9 layers. The layer adjacent to the substrate is referred to as a first layer and the outermost layer is referred to as a ninth layer. Each of the nine layers is respectively a L layer, an H layer, a L layer, an H layer, a L layer, an H layer, a L layer, an H layer, and a L layer from the first layer to the ninth layer. Material of the first layer as a L layer is aluminum oxide (Al₂O₃) and material of the other L layers is silicon dioxide (SiO₂). Each of the H layers is layer B previously described. The sum of values of thickness of the H layers of the multilayer film of Example 2 is 258 nanometers.

TABLE 4

| | |
|---|---|
| Number | Thickness of layer (nm) |

| of layer | Material of layer | Example1 | Example 2 |
|---|---|---|---|
| 9 | SiO₂ | | 149 |
| 8 | FeOx | | 64 |
| 7 | SiO₂ | 168 | 46 |
| 6 | FeOx | 35 | 65 |
| 5 | SiO₂ | 60 | 66 |
| 4 | FeOx | 51 | 64 |
| 3 | SiO₂ | 40 | 42 |
| 2 | FeOx | 61 | 65 |
| 1 | Al₂O₃ | 30 | 30 |
| 0 | Plastic substrate | | |

The target value of transmittance for light of wavelength of 850 nanometers of the thin film type filter for attenuating light of Example 1 is 50 percent and the target value of transmittance for light of wavelength of 850 nanometers of the thin-film type filter for attenuating light of Example 2 is 28 percent.

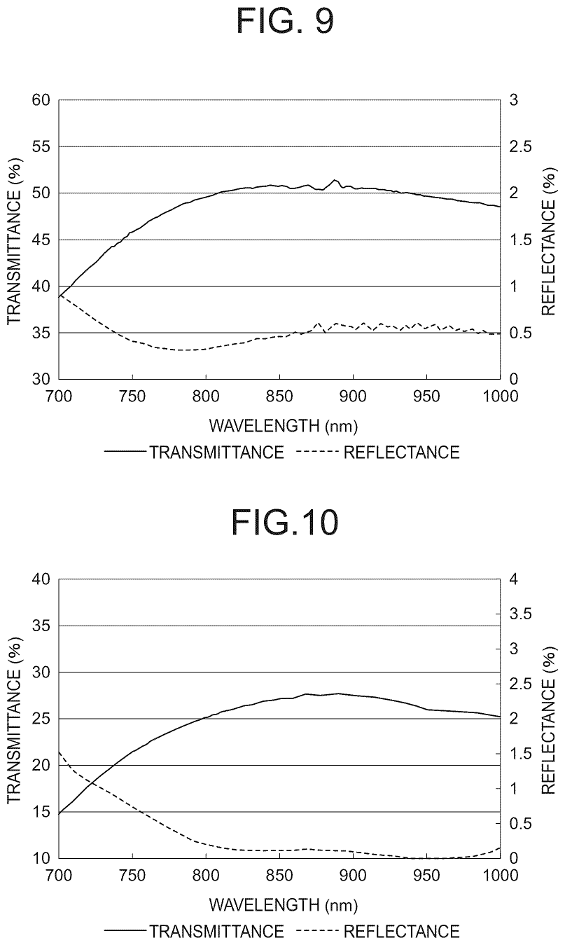

FIG. 9 shows transmittance and reflectance in a wavelength range of near infrared rays of the thin film type filter for attenuating light of Example 1. The horizontal axis of FIG. 9 indicates wavelength and the vertical axis of FIG. 9 indicates transmittance (on the scale on the left side) and reflectance (on the scale on the right side). The unit of wavelength is nanometer and the unit of transmittance and reflectance is percent. According to FIG. 9, transmittance of the thin film type filter for attenuating light of Example 1 is 51 percent and reflectance thereof is approximately 0.5 percent for light of wavelength of 850 nanometers.

FIG. 10 shows transmittance and reflectance in a wavelength range of near infrared rays of the thin-film type filter for attenuating light of Example 2. The horizontal axis of FIG. 10 indicates wavelength and the vertical axis of FIG. 10 indicates transmittance (on the scale on the left side) and reflectance (on the scale on the right side). The unit of wavelength is nanometer and the unit of transmittance and reflectance is percent. According to FIG. 10, transmittance of the thin film type filter for attenuating light of Example 2 is 27 percent and reflectance thereof is approximately 0.2 percent for light of wavelength of 850 nanometers.

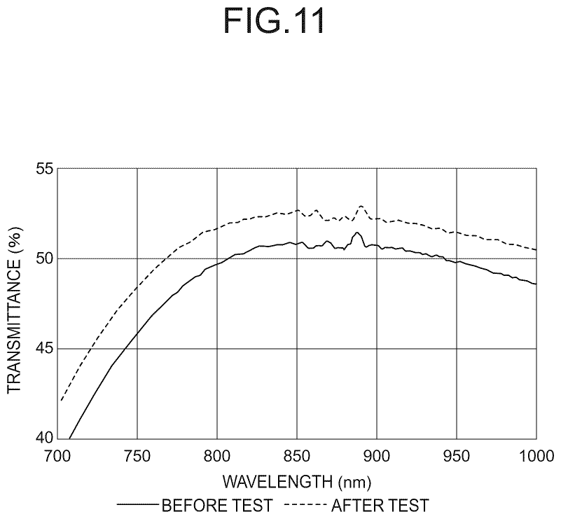

FIG. 11 shows transmittance before and after an environmental test in a wavelength range of near infrared rays of the thin-film type filter for attenuating light of Example 1.

The horizontal axis of FIG. 11 indicates wavelength and the vertical axis of FIG. 11 indicates transmittance. The unit of wavelength is nanometer and the unit of transmittance is percent. In the environmental test, the thin-film type filter for attenuating light of Example 1 formed on a substrate was held for hours in a saturated aqueous vapor of temperature of 121 degrees centigrade and pressure of 0.21 megapascal (MPa). Although transmittance increases because of development of oxidation of the iron oxide layers, an increase in transmittance is 3 percent or smaller and within a tolerable range.

In the examples described above, material of a L layer is aluminum oxide (Al₂O₃) or silicon dioxide (SiO₂). Material of a L layer can be magnesium fluoride (MgF₂), calcium fluoride (CaF₂), a mixture of silicon dioxide and silicon dioxide (SiO₂/Al₂O₃) or the like.

What is claimed is:

1. A thin-film type filter for attenuating light comprising a multilayer film including a layer or layers of iron oxide and a layer or layers of other material having refractive index lower than refractive index of iron oxide,
wherein the multilayer film comprises alternate layers of iron oxide and of other material, a ratio of the number of iron atoms to the number of oxygen atoms in each layer of iron oxide is equal to or greater than 4/3 and less than 3/2 and an attenuation coefficient of each layer of iron oxide is equal to or greater than 0.1 for light of a certain wavelength in a wavelength from 700 nanometers to 2000 nanometers.

2. The thin-film type filter for attenuating light according to claim 1, wherein the multilayer film includes plural layers of iron oxide and the maximum difference in attenuation coefficient between two layers of the plural layers of iron oxide is equal to or greater than 0.1 for light of wavelength of a certain wavelength in a wavelength from 700 nanometers to 2000 nanometers.

3. The thin-film type filter for attenuating light according to claim 1, wherein a value of thickness of the layer of iron oxide or the sum of the values of thickness of the layers of iron oxide is less than 500 nanometers.

4. The thin-film type filter for attenuating light according to claim 1, wherein the multilayer film is provided on a plastic substrate.

5. A method of producing a thin film type filter for attenuating light, the filter including a multilayer film including a layer or layers of iron oxide and a layer or layers of other material having refractive index lower than lower than refractive index of iron oxide, the method including
making up alternate layers of iron oxide and of other material, a ratio of the number of iron atoms to the number of oxygen atoms in each layer of iron oxide being equal to or greater than 4/3 and less than 3/2 and an attenuation coefficient of each layer of iron oxide being equal to or greater than 0.1 for light of a certain wavelength in a wavelength from 700 nanometers to 2000 nanometers,
wherein absorption of light of the multilayer film is adjusted by changing a ratio of the number of iron atoms to the number of oxygen atoms in each layer of iron oxide and a value of thickness of the layer of iron oxide or the sum of values of thickness of the layers of iron oxide.

6. The method of producing a thin-film type filter for attenuating light according to claim 5, wherein the multilayer film is formed in such a way that the multilayer film includes plural layers of iron oxide and a maximum difference in attenuation coefficient between two layers of the plural layers of iron oxide is equal to or greater than 0.1 for light of wavelength of a certain wavelength in a wavelength from 700 nanometers to 2000 nanometers.

7. The method of producing a thin film type filter for attenuating light according to claim 5, wherein the multilayer film is formed using a vacuum deposition method or a spattering method.
